(19) United States
(12) Patent Application Publication
(10) Pub. No.: US 2004/0032030 A1
(43) Pub. Date: Feb. 19, 2004

(54) Laser alignment structure

(75) Inventors: Kyle M. Flessner, Richardson, TX (US); Lyle R. Lazear, Rowlett, TX (US); Eugene B. Daniels, Van Alstyne, TX (US)

Correspondence Address: TEXAS INSTRUMENTS INCORPORATED, P O BOX 655474, M/S 3999, DALLAS, TX, 75265

(73) Assignee: Texas Instruments Incorporated, Dallas, TX (US)

(21) Appl. No.: 10/218,156

(22) Filed: Aug. 13, 2002

(51) Int. Cl. H01L 23/544

(52) U.S. Cl. 257/797

(57) ABSTRACT

A laser alignment structure and method for fabrication such a structure is provided. Preferably, the same material is used throughout the alignment structure. Contrast between different areas of the alignment structure is achieved by providing areas in the structure which are relatively flat and other areas which are not relatively flat having varying topographical features. The relatively flat areas reflect impinging laser energy substantially back in the direction from which it came (e.g., in a direction substantially perpendicular to a plane defined by the surface of the structure). The relatively non-flat areas reflect relatively little, if any, laser energy in the direction from which it came. Thus, although the entire surface of the alignment structure may be reflective of laser energy, the surface topology changes from one area to another thereby effectively changing the direction of the reflected laser energy.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

1. Field of the Invention

The present invention generally relates to the alignment of a laser. More particularly, the invention relates to a process and structure for aligning a laser used to trim a component on a semiconductor die such as a resistor or metal link. More particularly, the invention relates to an alignment structure that uses surface topology, rather than the reflectivity of different materials, to align a trimming laser.

2. Background Information

Many types of semiconductor dies require some form of laser trimming of one or more electrical components formed on the die. Trimming a component serves to adjust a characteristic of the component to a predetermined value or range of values. One example of a component that is typically trimmed is a resistor. The resistance of a resistor is, in part, a function of its length. Thus, by trimming the length of a resistor, the value of the resistance can be adjusted. Resistors on semiconductor dies typically include one or more fusible links coupling various points on the resistor to a conducting pathway. A resistor's resistance can be adjusted by “blowing” one or more of the fusible links. Blowing a fuse refers to the process of inducing physical damage to the extent the fuse is no longer electrically conductive. A laser is typically used to blow a fuse.

Trimming a resistor on a semiconductor die generally involves several steps. Because variations in the manufacturing process can cause the same resistor on different dies to have slightly different resistances, the first step is to measure the current value of the resistor. Once the resistor is measured, it then can be determined which, if any, of the resistor's fuses need to be blown to change the resistance to the desired value. The laser, however, must be aligned so that it then can be used to locate and blow the fuse. Alignment requires the laser system to identify a predetermined reference point on the die. Once aligned, the laser is then commanded, by computer control, to emit its energy at a precise point on the die at which a target fuse is located. The present disclosure provides an improved mechanism for aligning a laser.

The laser alignment process is illustrated conceptually beginning with FIG. 1. As shown, a plurality of individual dies 13 are formed on a wafer 11 in a grid pattern. One end 12 of the wafer is formed so as to be flat to allow proper orientation of the wafer crystal structure during processing and separation procedures. Each die 13 on a single wafer 11 is typically identical to all other dies on the wafer. One die 13a is shown having a laser alignment structure 17 and a component 19 to be trimmed by the laser. The laser locates the component 19 after being aligned using structure 17. This process is further explained in FIG. 2.

FIG. 2 depicts the single semiconductor die 13a from FIG. 1. Alignment structure 17 and trimmable component 19 are present as shown. Numerous other components are also included on the die(s) shown in FIGS. 1 and 2, but have been omitted for sake of clarity in explaining laser alignment. Alignment structure 17 is a conventional type of alignment structure comprising two orthogonally arranged metal leads 27a and 27b. An oxide material is formed on areas 23 adjacent the metal leads 27. The oxide material generally absorbs laser energy while the metal leads reflect the laser energy. The laser (not shown) preferably includes a detector that is sensitive to laser light reflected from the die and back up into the detector. As a laser beam traces across the die along, for example, line 29, the detector will generally not detect any, or much, laser energy reflected off the surface of the die due to the absorption characteristic of the oxide material in areas 23. However, as the laser beam crosses the metal reflective lead 27a, the laser energy is reflected back up into the detector and the detection system thereby can ascertain the location of the metal lead 27a.

Referring still to FIG. 2, once one metal lead 27a is located, the laser beam rescans the die, this time along an orthogonal line, for example, line 31. This time, the other metal lead 27b is located. Once both metal leads 27 are located, the alignment system can compute the location of a reference point 21 using well known geometry techniques. From there, all other locations on the die 13a can be referenced by, for example, a coordinate system (x,y).

Trimmable resistor 19 includes a conductive pathway 34 and one or more fuses 28, 30, 32. Although three fuses are shown, any number other than three can be included as desired. The resistor can be adjusted (i.e., trimmed) to a desired value by using the laser beam to blow one or more of the fuses. When a fuse is blown by a laser, the conductive pathway through the fuse is destroyed. The laser that blows a fuse is directed to the appropriate fuse to blow in accordance with an x,y coordinate of the target fuse referable to the reference point 21. Of course, an inaccurate alignment procedure will result in an incorrect fuse being blown or some other point on the die being undesirably destroyed by the laser. Thus, laser alignment is important to accurately trimming resistors and other trimmable components.

The alignment structure 17 described above uses two disparate types of material—one being reflective of laser energy (the metal strips 27), the other absorbing laser energy (the oxide material in areas 23). This provides the needed contrast to be able to determine the location of leads 27 on the die. Although this type of alignment structure is satisfactory in some instances, it does not work in every instance. In some instances, the detection system does not detect enough of a contrast between the laser energy it receives when over the oxide layer as compared to the metal leads. At the present time, it is not known why the conventional alignment mechanism depicted in FIG. 2 does not always work satisfactorily. Nevertheless, an improved alignment mechanism is needed.

### BRIEF SUMMARY OF THE PREFERRED EMBODIMENTS OF THE INVENTION

The preferred embodiments of the present invention solve the problems noted above by providing an improved laser alignment structure and method for fabrication of such a structure. Preferably, although not a requirement, the same material is used throughout the alignment structure. Contrast between different areas of the alignment structure is achieved, not by using materials with different reflective properties as explained above, but by providing areas in the structure which are relatively flat and other areas which are not relatively flat. The relatively flat areas reflect impinging laser energy substantially back in the direction from which it came (e.g., in a direction substantially perpendicular to a plane defined by the surface of the structure). The relatively non-flat areas reflect relatively little, if any, laser energy in the direction from which it came. Thus, although the entire surface of the alignment structure may be reflective of laser energy, the surface topology changes from one area to another thereby effectively changing the direction of the reflected laser energy.

A preferred embodiment of the improved alignment structure comprises a first area that is usable to reflect energy from the laser into a laser detector and a second area adjacent the first area and formed from the same material as the first area. The second area preferably is not usable to reflect energy from the laser into the laser detector. The first area preferably comprises one or more reflective metal strips. The second area preferably is relatively non-flat so that little, if any, laser energy is reflected back into the laser detector. Instead, the laser energy is reflected in other directions. The second area preferably comprises three regions formed adjacent the metal strips. The second area is formed as a grid of raised surface contacts, or other types of raised structures, which define valleys or interstices therebetween.

The raised structures have a predetermined width and a height and the interstices between the raised structures also have a predetermined width. In general, it is desirable for the widths of the raised structures and the interstices to be relatively small and the height of the raised structures to be relatively large. These dimensions are, at least to a certain extent, a function of the wavelength of the laser energy used to trim the trimmable components. Because trimmable components can be trimmed with lasers having a variety of different wavelengths, the distances defined noted above can be varied as is appropriate. In accordance with one preferred embodiment, the width of an interstices and raised structures should be minimized while the height of the raised structure is preferably maximized per technology limitations.

By basing the reflective properties of an alignment structure on surface topology, rather than the use of dissimilar materials, an improved alignment structure is obtained. These and other aspects of the preferred embodiments of the present invention will become apparent upon analyzing the drawings, detailed description and claims, which follow.

### BRIEF DESCRIPTION OF THE DRAWINGS

For a detailed description of the preferred embodiments of the invention, reference will now be made to the accompanying drawings in which:

FIG. 1 shows a plurality of semiconductor dies fabricated on a wafer;

FIG. 2 shows one such die having a conventional laser alignment structure and a trimmable component;

FIG. 3 shows a close-up view of the laser alignment structure of FIG. 2 in accordance with a preferred embodiment;

FIG. 4 shows a further close-up cross-sectional view of a portion of the preferred laser alignment structure in which surface contacts provide a mechanism to reflect laser energy away from a laser detector;

FIG. 5 shows one preferred embodiment of an arrangement of the surface contacts or other topography; and

FIG. 6 shows another preferred embodiment of an arrangement of the surface contacts or other topography.

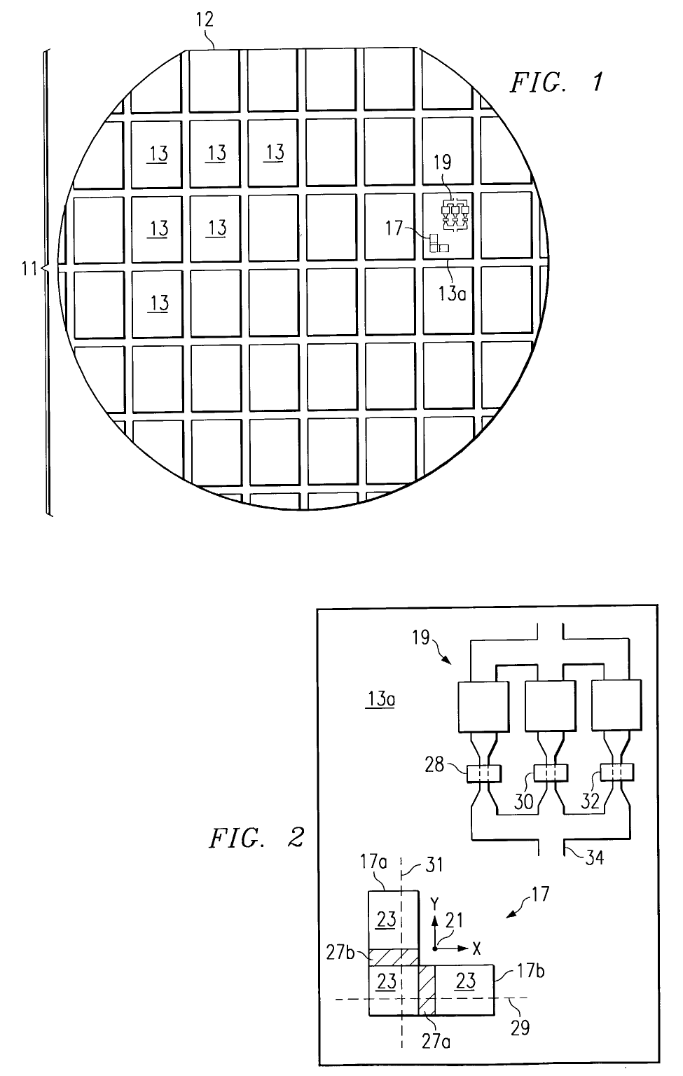

### NOTATION AND NOMENCLATURE

Certain terms are used throughout the following description and claims to refer to particular system components. As one skilled in the art will appreciate, semiconductor companies may refer to a component and sub-components by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either a direct or indirect electrical connection. Thus, if a first device couples to a second device, that connection may be through a direct electrical connection, or through an indirect electrical connection via other devices and connections. To the extent that any term is not specially defined in this specification, the intent is that the term is to be given its plain and ordinary meaning.

### DETAILED DESCRIPTION OF THE PREFERRED EMBODIMENTS

In accordance with a preferred embodiment of the invention, an alignment structure comprises at least two areas having different surface topologies. One area is relatively flat, while the other area is non-flat and adjacent the first area. Both areas preferably reflect laser energy and may even be made of the same material (e.g., metal). The flat area preferably is usable to reflect laser energy from the laser into a laser detector. The non-flat area preferably is not usable to reflect laser energy into the laser detector. Instead, the non-flat area reflects laser energy away from the detector. The laser generally emits its laser beam down toward the surface of the die and the alignment structure in a direction that is approximately perpendicular to a plane defined by the surface of the alignment structure. The flat portion of the alignment structure reflects the laser energy in the direction from which it came (i.e., substantially perpendicular to the alignment structure. The non-flat area does not reflect its laser energy in a direction substantially perpendicular to the alignment structure.

Referring now to FIG. 3, a laser alignment structure 100 is shown constructed in accordance with a preferred embodiment of the invention. The alignment structure 100 generally comprises two alignment strips 102 and 104 arranged between three areas 106, 108, and 110 as shown. Strips 102 and 104 form the flat area noted above, while areas 106-110 form the non-flat area noted above. As will be explained in detail below, areas 106, 108 and 110 preferably are made from the same type of material as strips 102. As explained previously, the mechanism by which the laser detects and discerns the strips 102, 104 from the surrounding areas 106-110 is based on different surface geometry or topology of areas 106-110 than the strips 102, 104, not a difference in reflective material as discussed above with respect to traditional alignment structures. In accordance with a preferred embodiment of the invention, the areas surrounding the strips 102, 104 comprise a relatively dense array of surface contacts or other topography that reflect laser energy, but away form the laser detector.

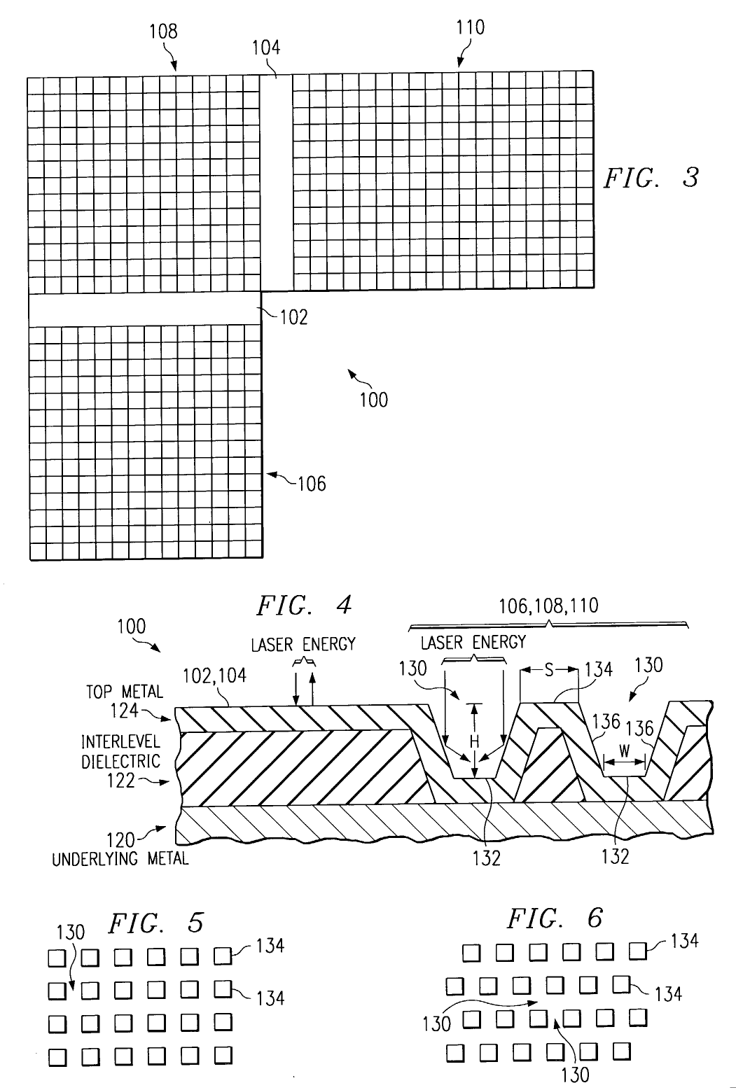

FIG. 4 shows a close-up cross-sectional view of part of the alignment structure 100. As shown, the alignment structure preferably includes an underlying metal layer 120 onto which an inter-level dielectric or other non-conductive layer 122 is bonded or otherwise formed. Then, a top metal layer 124 is formed thereon. The drawing depicts part of a relatively flat strip 102, 104 on the left-hand side of the drawing and part of a non-flat surrounding area 106-110 on the right side. In accordance with a preferred embodiment, the areas 106-110 include a plurality of relatively closely spaced and raised surface contacts 134 spaced apart by valleys or interstices 130 defined at their bottom end by lower surfaces 132. The side walls 136 forming the topography 134 may be angled as shown or perpendicular to the underlying layer.

As the laser beam scans across the preferred alignment structure 100, the laser energy encounters the top metal layer 124 and not the oxide layer 122. When the laser beam is directed down at the surface of the metal strips 102, 104, the laser energy is reflected back up into the laser detector as shown in FIG. 3. However, as the laser scans over to an area 106-110, which also comprises reflective metal, the laser energy reflects at various angles off the side walls 136, lower surface 132 and topography 134, but generally not straight back up into the laser detector. Thus, although the strips 102, 104 and surrounding areas 106-110 are all preferably formed from reflective material, the surface topology of non-flat areas 106-110 is such that relatively little laser energy is reflected into a laser detector. In accordance with a preferred embodiment of the invention, preferably a difference of more than 30% exists between the incident laser energy reflected back into the detector from the flat areas 102 and 104 and the incident laser energy reflected back into the detector from the non-flat areas 106-110.

FIG. 5 shows a top view of a portion of an area 106-110. The area preferably comprises a grid or array of surface contacts or other topography 134 separated by interstices 130. The contacts or other topography 134 may be arranged in rows in which the contacts or other topography 134 are in alignment as shown. Alternatively, the contacts or other topography may be offset from one row to another as shown in FIG. 6.

Referring again to FIG. 4, the width of the valleys 132 is designated as W while the width of the surface contacts 134 is designated as S. The height of each surface contact 134 is designated as H. In general, it is desirable to have a relatively small S and W and a large H. The dimensions of H, S, and W are, at least to a certain extent, a function of the wavelength of the laser energy. Trimmable components can be trimmed with lasers having different wavelengths and thus S, H and W can be varied as is appropriate. In accordance with the preferred embodiment. W and S should be preferably minimized while H is preferably maximized per technology limitations. For example, W and S preferably are less than about 1.2 microns and H preferably is greater than about 40000 Angstroms.

Thus, the preferred embodiment of the invention achieves the contrast needed to for a laser alignment system to differentiate an alignment strip from surrounding surface area. Rather than achieving the desired contrast by using materials having differing reflective properties, the preferred embodiments use the same material but with a surface topology that reflects the laser energy either back up into the laser detector or in other directions. Moreover, the embodiments described herein provide a significant advance over conventional laser alignment techniques.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An alignment structure formed on a semiconductor die for aligning a laser trimming system containing a laser and a laser detector, said alignment structure comprising:
a first area that is usable to reflect energy from the laser into said laser detector; and
a second area adjacent the first area and formed from the same material as the first area, said second area not usable to reflect energy from the laser into said laser detector.

2. The alignment structure of claim 1 wherein said first area comprises a metal strip.

3. The alignment structure of claim 2 wherein said first area comprises a pair of metal strips.

4. The alignment structure of claim 1 wherein said first area is relatively flat and said second area is relatively non-flat whereby 30% or more laser energy is reflected off the first area into said laser detector than from the second area into said laser detector.

5. The alignment structure of claim 1 wherein said second area comprises a plurality of peaks and valleys.

6. The alignment structure of claim 1 wherein said second area is made from a reflective material and comprises a plurality of surface contacts separated by interstices.

7. The alignment structure of claim 6 wherein each of said surface contacts has a width that is less than about 1.2 microns.

8. The alignment structure of claim 6 wherein the height of each surface contact is greater than about 4000 Angstroms.

9. The alignment structure of claim 6 wherein the width of each valley is less than about 1.2 microns.

10. The alignment structure of claim 6 wherein said contacts are arranged in a plurality of rows.

11. The alignment structure of claim 6 wherein said contacts are arranged in a plurality of rows, each row offset from an adjacent row.

12. An alignment structure formed on a semiconductor die for aligning a laser trimming system containing a laser and a laser detector, comprising:
a relatively flat first area that is usable to reflect energy from the laser into said laser detector; and
a relatively non-flat second area adjacent the first area, said second area not usable to reflect energy from the laser into said laser detector.

13. The alignment structure of claim 12 wherein said first area comprises a metal strip.

14. The alignment structure of claim 13 wherein said first area comprises a pair of metal strips.

15. The alignment structure of claim 12 wherein said first area is relatively flat and said second area is relatively non-flat whereby 30% or more laser energy is reflected off the first area into said laser detector than from the second area into said laser detector.

16. The alignment structure of claim 12 wherein said second area comprises a plurality of peaks and valleys.

17. The alignment structure of claim 12 wherein said second area is made from a reflective material and comprises a plurality of surface contacts separated by interstices.

18. The alignment structure of claim 17 wherein each of said surface contacts has a width that is less than about 1.2 microns.

19. The alignment structure of claim 17 wherein the height of each surface contact is greater than about 4000 Angstroms.

20. The alignment structure of claim 17 wherein the width of each valley is less than about 1.2 microns.

21. The alignment structure of claim 17 wherein said contacts are arranged in a plurality of rows.

22. The alignment structure of claim 17 wherein said contacts are arranged in a plurality of rows, each row offset from an adjacent row.

23. An alignment structure formed on a semiconductor die for aligning a laser trimming system containing a laser and a laser detector, comprising:
a pair of metal trips formed at an orthogonal to one another, said metal strips usable to reflect energy from the laser into said laser detector; and
a plurality of areas adjacent said metal strips, said areas being substantially non-reflective of laser energy in a direction perpendicular to the surface of said areas.

24. A semiconductor die, comprising:
a trimmable component; and
an alignment structure used to align a laser trimmer for said trimmable component, said alignment structure including:
a first area substantially reflective of laser energy from said laser trimmer in a direction substantially perpendicular to a plane defined by said alignment structure; and
a second area substantially non-reflective of the laser energy in the direction substantially perpendicular to the plane.

25. The semiconductor die of claim 24 wherein said trimmable component comprises a component selected from the group consisting of resistor and metal link.

26. The semiconductor die of claim 24 wherein said first area comprises a pair of metal, relatively flat, reflective strips formed at approximately a 90 degree angle to each other.

27. The semiconductor die of claim 26 wherein said second area comprises at least three metal regions adjacent said metal strips, said metal regions formed with a repeating pattern of raised surface portions defining interstitial spaces between said raised surface portions.

28. A method of forming an alignment structure on a semiconductor die, said alignment structure used to align a laser trimmer, said method comprising:
forming a dielectric layer on a wafer, a portion of said dielectric layer comprising raised dielectric formations; and
forming a metal layer on top of said dielectric layer resulting in a relatively flat region adjacent a non-flat region.

29. The method of claim 28 wherein said non-flat region includes raised metal formations separated by interstices, said metal formations separated by less than about 1.2 microns.

30. The method of claim 29 wherein the height of said raised metal formations is greater than about 4000 Angstroms.

31. The method of claim 28 wherein the width of said raised metal formations is less than about 1.2 microns.

32. An alignment structure formed on a semiconductor die for aligning a laser trimming system containing a laser and a laser detector, comprising:
a means for reflecting laser energy received from a laser into a laser detector; and
a means for reflectively diverting laser energy away from said laser detector.
